(19) United States
(12) Patent Application Publication
(10) Pub. No.: US 2024/0241153 A1
(43) Pub. Date: Jul. 18, 2024

(54) SPRING PROBE CONTACT ASSEMBLY

(71) Applicant: Johnstech International Corporation, Minneapolis, MN (US)

(72) Inventor: Valts Treibergs, White Bear Township, MN (US)

(21) Appl. No.: 18/408,107

(22) Filed: Jan. 9, 2024

Related U.S. Application Data
(60) Provisional application No. 63/479,663, filed on Jan. 12, 2023.

(51) Int. Cl. G01R 1/067; G01R 1/073

(52) U.S. Cl. CPC G01R 1/06722; G01R 1/07314; H01R 13/2421

(57) ABSTRACT

A compliant probe contact assembly for a testing system for testing integrated circuit devices is provided. The contact assembly includes an upper plunger including a first shoulder separating an upper shaft from a lower shaft, and a retainer proximate an end of the lower shaft. The contact assembly also includes a first receiver and a second receiver configured to engage with the upper plunger, each of the first and second receivers including a second shoulder having a shoulder stop. The contact assembly further includes a biasing member. When the contact assembly is assembled, the biasing member is captured between a bottom of the first shoulder and the shoulder stops of the first and second receivers. The upper plunger separates sides of upper portions of the first and second receivers. Sides of lower portions of the first and second receivers contact with each other.

### TECHNICAL FIELD

This disclosure relates generally to the field of testing microcircuits (e.g., chips such as semiconductor devices, integrated circuits, etc.). More specifically, the disclosure relates to a spring loaded probe contact assembly that provides electrical connection to a device under test (DUT).

### BACKGROUND

The manufacturing processes for microcircuits cannot guarantee that every microcircuit is fully functional. Dimensions of individual microcircuits are microscopic and process steps very complex, so small or subtle failures in a manufacturing process can often result in defective devices. Mounting a defective microcircuit on a circuit board is relatively costly. Installation usually involves soldering the microcircuit onto the circuit board. Once mounted on a circuit board, removing a microcircuit is problematic because the very act of melting the solder for a second time may ruin the circuit board. Thus, if the microcircuit is defective, the circuit board itself is probably ruined as well, meaning that the entire value added to the circuit board at that point is lost. For all these reasons, a microcircuit is usually tested before installation on a circuit board. Each microcircuit must be tested in a way that identifies all defective devices, but yet does not improperly identify good devices as defective. Either kind of error, if frequent, adds substantial overall cost to the circuit board manufacturing process.

Microcircuit test equipment itself is quite complex. First of all, the test equipment must make accurate and low resistance temporary and non-destructive electrical contact with each of the closely spaced microcircuit contacts. Because of the small size of microcircuit contacts and the spacing between them, even small errors in making the contact will result in incorrect connections. A further problem in microcircuit test equipment arises in automated testing. Testing equipment may test one hundred devices a minute, or even more. The sheer number of tests cause wear on the tester contacts making electrical connections to the microcircuit terminals during testing.

Other considerations exist as well. Inexpensive tester contacts that perform well are advantageous. Minimizing the time required to replace them is also desirable, since test equipment is expensive. If the test equipment is off line for extended periods of normal maintenance, the cost of testing an individual microcircuit increases. Test equipment in current use has an array of test contacts that mimic the pattern of the microcircuit terminal array. The array of test contacts is supported in a structure that precisely maintains the alignment of the contacts relative to each other. The test contacts are mounted on a load board (i.e., a printed circuit board (PCB)) having conductive pads that make electrical connection to the test contacts. The load board pads are connected to circuit paths that carry the signals and power between the test equipment electronics and the test contacts.

### BRIEF SUMMARY

Test contactors are often designed and built using spring loaded contacts, because of the simplicity of design of the socket, yet robust and reliable electrical contacts for ball grid array (BGA) packages and/or other array-style integrated circuit packages. The spring loaded contacts form the temporary electrical connections between the DUT and the load board. Each contact (or contact assembly) connects a particular terminal (e.g., a signal and power (S&P) terminal) on the DUT to a particular pad on the load board. It is to be understood that the DUT can have a BGA package or any other suitable package(s). For example, the DUT can be a pad device, a peripheral device, etc.

Embodiments disclosed herein provide a solution that addresses each of the above-mentioned problems. Embodiments disclosed herein provide a compliant spring loaded probe contact assembly including an upper plunger (DUT plunger) and a pair of receivers (aka, lower plungers, PCB plungers, or load board plungers) that are entrapped by a biasing member such as a compliant compression spring.

The probe contact assembly disclosed herein can have significant improvements to the existing design that enhance the electrical and mechanical performance of the spring loaded probe. The probe contact assembly disclosed herein can use multiple manufacturing technologies to make the plunger components of the spring loaded probe contact assembly, and the probe contact assembly may not be restricted to using one single technology. The probe contact assembly disclosed herein is capable to use a homogenous alloy DUT side tip, uses two identical PCB side plunger components that are manufactured from flat-forming processes, such as etching, stamping, water-jet cutting, or e-forming. The use of two PCB side plunger components that contact the PCB pad can be beneficial because of electrical redundancy.

The internal geometry of the probe contact assembly can be designed such that the geometry (e.g., the internal geometry of the spring) can captivate and retain the components (e.g., inside the internal volume of the spring), while making a reliable sliding interconnect between the upper plunger and the receiver pair. The probe contact assembly disclosed herein does not rely on deforming, crimping, snapping a latch (or latches) or press-fitting a spring. For the probe contact assembly disclosed herein, the geometry of the components alone can captivate the probe contact assembly when the probe contact assembly is assembled, and the probe contact assembly may not physically disengage itself during normal usage.

The probe contact assembly disclosed herein can decrease the overall length of the assembly, which can lower the probe inductance and increase the radio frequency (RF) performance. In contrast, existing latching and press-fit technologies may require extended areas of length to achieve positive latching or need features large enough to allow crimping or deforming to reliable hold the assembly together.

The probe contact assembly disclosed herein can be used in a standard socket housing that is most typically precision machined, can be extremely miniaturized, and can be essential for testing 5G and other high frequency semiconductor devices, due to its inherent low inductance. The external spring geometry and internal assembly design of the probe contact assembly can allow for a large percentage of compliance in the probe contact assembly, which can be important for testing BGA packages or when multiple DUTs are to be tested at once, because of extra mechanical tolerances in the test system.

The probe contact assembly disclosed herein can have components captured within the spring volume which ensures that the sliding interfaces (e.g., between sides of the receivers and the internal shaft of the upper plunger) are always in contact with each other. The fit of these components can ensure a reliable electrical contact of the plungers and the receivers can contact the inner wire surfaces of the spring, which can be desirable as a redundant contact element in the system and can minimize the possibility of RF resonances that may be induced at undesirable frequencies.

Also disclosed is a compliant probe contact assembly for a testing system for testing integrated circuit devices. The contact assembly includes an upper plunger including a first shoulder separating an upper shaft from a lower shaft, and a retainer proximate an end of the lower shaft. The contact assembly also includes a first receiver and a second receiver configured to engage with the upper plunger, each of the first and second receivers including a second shoulder having a shoulder stop. The contact assembly further includes a biasing member. When the contact assembly is assembled, the biasing member is captured between a bottom of the first shoulder and the shoulder stops of the first and second receivers. The upper plunger separates sides of upper portions of the first and second receivers. Sides of lower portions of the first and second receivers contact with each other.

Also disclosed is a testing system for testing integrated circuit devices. The testing system includes a device under test (DUT), a load board, and a compliant probe contact assembly. The contact assembly includes an upper plunger including a first shoulder separating an upper shaft from a lower shaft, and a retainer proximate an end of the lower shaft. The contact assembly also includes a first receiver and a second receiver configured to engage with the upper plunger, each of the first and second receivers including a second shoulder having a shoulder stop. The contact assembly further includes a biasing member. When the contact assembly is assembled, the biasing member is captured between a bottom of the first shoulder and the shoulder stops of the first and second receivers. The upper plunger separates sides of upper portions of the first and second receivers. Sides of lower portions of the first and second receivers contact with each other. The upper plunger includes a DUT interface configured to engage with the DUT. An end of the first and second receivers is configured to engage with the load board.

Also disclosed is a compliant probe contact assembly for a testing system for testing integrated circuit devices. The contact assembly includes a plunger including a retainer proximate an end of a lower shaft; and first and second receiver plates having a top and a bottom, each receiver plate having a longitudinal aperture sized to receive only a portion of the retainer, the aperture being not wide enough to allow the retainer to pass therethrough. The contact assembly also includes and a biasing member. The first and second receiver plates are aligned relative to each other so that the first and second receiver plates are progressively closer to each other at the bottom relative to the top. When the contact assembly is assembled, the biasing member surrounds at least a portion of the plunger and receives the first and second receiver plates thereby holding the first and second receiver plates and the retainer in physical and electrical contact as the plunger moves long the aperture of the first and second receiver plates.

### BRIEF DESCRIPTION OF THE SEVERAL VIEWS OF THE DRAWINGS

References are made to the accompanying drawings that form a part of this disclosure and which illustrate embodiments in which the systems and methods described in this specification can be practiced.

FIG. 1A is a perspective view of a part of a test system for receiving a DUT for testing, according to an embodiment.

FIG. 1B is a perspective bottom view of a DUT, according to an embodiment.

FIG. 1C is a side-view drawing of a portion of the test system for receiving a DUT, according to an embodiment.

FIG. 1D is a side-view drawing of the test system of FIG. 1C, with the DUT electrically engaged, according to an embodiment.

FIG. 2A is a side view of an upper plunger of a probe contact assembly for a testing system, according to an embodiment.

FIG. 2B is a perspective view of the upper plunger of FIG. 2A, according to an embodiment.

FIG. 3A is a front view of a receiver of a probe contact assembly for a testing system, according to an embodiment.

FIG. 3B is a perspective view of the receiver of FIG. 3A, according to an embodiment.

FIG. 4A is a side view of a spring of a probe contact assembly for a testing system, according to an embodiment.

FIG. 4B is a perspective view of the spring of FIG. 4A, according to an embodiment.

FIG. 5A is a front view of a probe contact assembly for a testing system, according to an embodiment.

FIG. 5B is a side view of the probe contact assembly of FIG. 5A, according to an embodiment.

FIG. 5C is a perspective view of the probe contact assembly of FIG. 5A, according to an embodiment.

FIG. 5D is a top view of the probe contact assembly of FIG. 5A, according to an embodiment.

FIG. 5E is a bottom view of the probe contact assembly of FIG. 5A, according to an embodiment.

FIG. 6A is a front view of a probe contact assembly (in a compressed state) for a testing system, according to another embodiment.

FIG. 6B is a side view of the probe contact assembly of FIG. 6A, according to another embodiment.

FIG. 6C is a perspective view of the probe contact assembly of FIG. 6A, according to another embodiment.

FIG. 6D is a top view of the probe contact assembly of FIG. 6A, according to another embodiment.

FIG. 6E is a bottom view of the probe contact assembly of FIG. 6A, according to another embodiment.

FIG. 7A is a top view of a probe contact assembly for a testing system, according to an embodiment.

FIG. 7B is a front view of the probe contact assembly of FIG. 7A, according to an embodiment.

FIG. 7C is a cross-sectional view of the probe contact assembly of FIG. 7A along the line A-A, according to an embodiment.

FIG. 7D is a cross-sectional view of the probe contact assembly of FIG. 7A along the line B-B, according to an embodiment.

FIG. 8A is a top view of a probe contact assembly (in a compressed state) for a testing system, according to another embodiment.

FIG. 8B is a front view of the probe contact assembly of FIG. 8A, according to another embodiment.

FIG. 8C is a cross-sectional view of the probe contact assembly of FIG. 8A along the line C-C, according to another embodiment.

FIG. 8D is a cross-sectional view of the probe contact assembly of FIG. 8A along the line D-D, according to another embodiment.

FIG. 9A is a front view of a probe contact assembly for a testing system, according to an embodiment.

FIG. 9B is a cross-sectional view of the probe contact assembly of FIG. 9A along the line E-E, according to an embodiment.

FIG. 10A is a cross sectional perspective view of a plurality of probe contact assemblies housed in a socket housing, according to an embodiment.

FIG. 10B is an enlarged view of a portion F1 of FIG. 10A, illustrating a probe contact assembly housed in a contact cavity of a socket housing, according to an embodiment.

FIG. 11A is a cross sectional perspective view of a plurality of probe contact assemblies (in a compressed state) housed in a socket housing, according to another embodiment.

FIG. 11B is an enlarged view of a portion F2 of FIG. 11A, illustrating a probe contact assembly housed in a contact cavity of a socket housing, according to another embodiment.

FIG. 12A is a front view of a receiver (in a flat state as manufactured) of a probe contact assembly for a testing system, according to another embodiment.

FIG. 12B is a perspective view of the receiver of FIG. 12A in a folded state, according to another embodiment.

FIG. 13A is a perspective view of a probe contact assembly, according to an embodiment.

FIG. 13B is a perspective view of a probe contact assembly in a compressed state, according to another embodiment.

FIG. 14A is a front view of a receiver (in a flat state as manufactured) of a probe contact assembly for a testing system, according to yet another embodiment.

FIG. 14B is a perspective view of the receiver of FIG. 14A in a folded state, according to yet another embodiment.

FIG. 15A is a perspective view of a probe contact assembly, according to an embodiment.

FIG. 15B is a perspective view of a probe contact assembly in a compressed state, according to another embodiment.

FIG. 16A is a front view of a receiver of a probe contact assembly for a testing system, according to yet another embodiment.

FIG. 16B is a perspective view of the receiver of FIG. 16A, according to yet another embodiment.

FIG. 17A is a front view of a probe contact assembly, according to an embodiment.

FIG. 17B is a side view of the probe contact assembly of FIG. 17A, according to an embodiment.

FIG. 17C is a perspective view of the probe contact assembly of FIG. 17A, according to an embodiment.

FIG. 17D is a front view of a probe contact assembly in a compressed state, according to another embodiment.

FIG. 17E is a side view of the probe contact assembly of FIG. 17D, according to another embodiment.

FIG. 17F is a perspective view of the probe contact assembly of FIG. 17D, according to another embodiment.

Like reference numbers represent like parts throughout.

### DETAILED DESCRIPTION

A test contactor (i.e., a part of a test assembly including alignment plate, socket, etc.) can often provide electrical connection to a DUT including e.g., S&P terminals of the DUT by making metal-to-metal contact to the printed circuit board (e.g., the load board, including e.g., S&P terminals of the load board). A contact assembly that has compliance has advantages in testing by accommodating DUT package variation. It will be appreciated that the term “compliance” may refer to a property of a material of undergoing elastic deformation or change in volume when subjected to an applied force. Compliance can be equal to the reciprocal of stiffness.

The terminals of a DUT can be temporarily electrically connected to corresponding contact pads on a load board by a series of electrically conductive contacts. The terminals may be pads, balls, wires (leads) or other contact points. Each terminal connects with a contact, which electrically connects to a respective contact pad on the load board.

Embodiments disclosed herein provide a spring loaded probe contact assembly with high performance (e.g., high RF performance, etc.), with low inductance, and at low cost. The height of the contact assembly can be scalable. In an embodiment, the height of the contact assembly can be at or around one mm, and a diameter of the contact assembly or spring can be at or about 100 microns to at or about 250 microns.

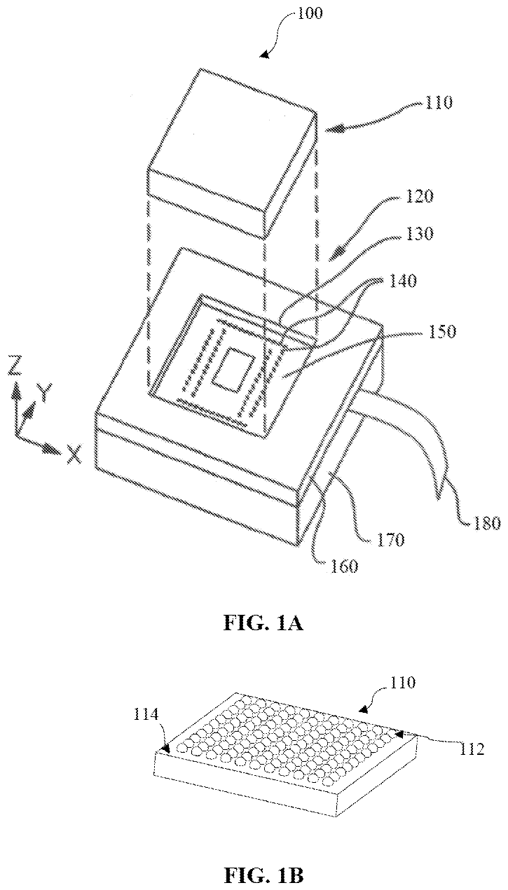

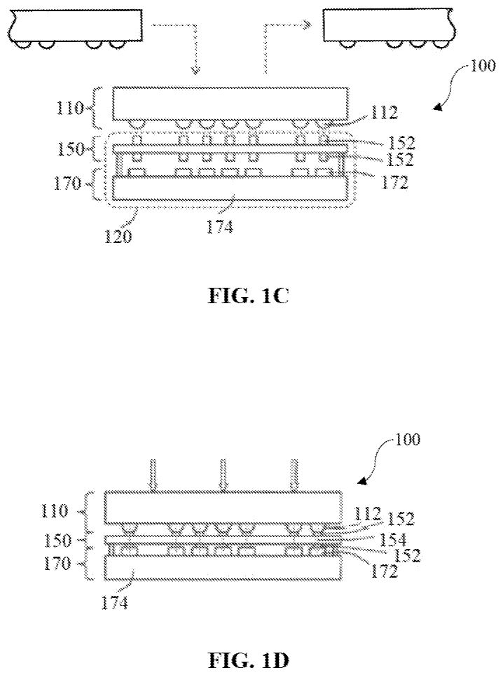

FIG. 1A is a perspective view of a part of a test system 100 for receiving a DUT 110 for testing, according to an embodiment.

The test system 100 includes a test assembly 120 for a DUT (e.g., a microcircuit, etc.) 110. The test assembly 120 includes a load board 170 that supports an alignment plate 160 having an opening or aperture 130 that precisely defines the X and Y (see the coordinate indicators X and Y, where the coordinate X is perpendicular to the coordinate Y, and the coordinate Z is perpendicular to the plane of X and Y) positioning of the DUT 110 in test assembly 120. If the DUT 110 has orientation features, it is common practice to include cooperating features in aperture 130. Load board 170 carries on its surface, connection pads connected to a cable 180 by Signal and Power (S&P) conductors. Cable 180 connects to the electronics that perform that electrical testing of the DUT 110. Cable 180 may be very short or even internal to the test assembly 120 if the test electronics are integrated with the test assembly 120, or longer if the test electronics are on a separate chassis. It will be appreciated that the cable 180 can be optional. In another embodiment, the load board can be connected to test electronics by any other suitable means, including but not limited to e.g., spring loaded probes.

A test contact array 140 having a number of individual test contact elements precisely mirrors the S&P terminals (see 112 in FIG. 1B) carried on the surface of the DUT 110. When the DUT 110 is inserted in the aperture 130, S&P terminals of the DUT 110 precisely align with test contact array 140. The test assembly 120 is designed for compatibility with a test contact array 140 incorporating the device. Test contact array 140 is carried on a socket 150. Individual test contacts in array 140 are preferably formed on and in socket 150 using well-known photolithographic and laser machining processes. Socket 50 has alignment features such as holes or edge patterns located in the area between alignment plate 160 and load board 170 that provide for precise alignment of socket 150 with corresponding projecting features on alignment plate 160. All of the test contacts 140 are in precise alignment with the socket 150 alignment features. In this way, the test contacts of array 140 are placed in precise alignment with aperture 130.

FIG. 1B is a perspective bottom view of a DUT 110, according to an embodiment. The DUT (e.g., a microcircuit, etc.) 110 includes a top main surface (not shown), and a bottom main surface 114 opposite to the top main surface in the Z (see the coordinate indicators X, Y, and Z in FIG. 1A) direction. In an embodiment, the DUT 110 can have BGA packages. In some embodiments, the DUT 110 can have flat no-leads packages such as quad-flat no-leads (QFN) and dual-flat no-leads (DFN). Flat no-leads, also known as micro lead-frame (MLF) and SON (small-outline no leads), is a surface-mount technology, one of several package technologies that connect the DUT 110 to the surfaces of e.g., socket 150 or other printed circuit boards (PCBs) without through-holes. In one embodiment, flat no-lead can be a near chip scale plastic encapsulated package made with a planar copper lead frame substrate. Perimeter lands (e.g., terminals 112) on the package bottom provide electrical connections to the socket 150 or the PCB. Flat no-lead packages can include an exposed thermally conductive pad to improve heat transfer out of the DUT 110 (e.g., into the PCB). The QFN package can be similar to the quad-flat package (QFP). In an embodiment, the DUT 110 can be wafer-level chip scale package (WL-CSP), leaded package such as thin small outline package (TSOP) or diode outline (DO) package, or the like.

FIG. 1C is a side-view drawing of a portion of the test system 100 for receiving the DUT 110, according to an embodiment. FIG. 1D is a side-view drawing of the test system 100 of FIG. 1C, with the DUT 110 electrically engaged, according to an embodiment.

As shown in FIG. 1C, the DUT 110 is placed onto the test assembly 120, electrical testing is performed, and the DUT 110 is then removed from the test assembly 120. Any electrical connections are made by pressing components into electrical contact with other components; there is no soldering or de-soldering at any point in the testing of the DUT 110. The entire electrical test procedure may only last about a fraction of a second, so that rapid, accurate placement of the DUT 110 becomes important for ensuring that the test system 100 is used efficiently. The high throughput of the test assembly 120 usually requires robotic handling of the DUT 110. In most cases, an automated mechanical system places the DUT 110 onto the test assembly 120 prior to testing, and removes the DUT 110 once testing has been completed. The handling and placement mechanism may use mechanical and optical sensors to monitor the position of the DUT 110, and a combination of translation and rotation actuators to align and place the DUT 110 on or in the test assembly 120. Alternatively, the DUT 110 may be placed by hand, or placed by a combination of hand-fed and automated equipment.

The DUT 110 typically includes signal and power terminals 112 (see also terminals 112 of FIG. 1B) that connect to the socket 150 or other PCBs. The terminals may be on one side of the DUT 100, or may be on both sides of the DUT 110. For use in the test assembly 120, all the terminals 112 should be accessible from one side of the DUT 110, although it will be understood that there may be one or more elements on the opposite side of the DUT 110, or that there may be other elements and/or terminals on the opposite side that may not be tested by accessing terminals 112. Each terminal 112 is formed as a small, pad on button side of the DUT 110 or possibly a lead (e.g., half-ball shaped) protruding from the body of the DUT 110. Prior to testing, the pad or lead 112 is attached to an electrical lead that connects internally to other leads, to other electrical components, and/or to one or more chips in the DUT. The volume and size of the pads or leads may be controlled quite precisely, and there is typically not much difficulty caused by pad-to-pad or lead-to-lead size variations or placement variations. During testing, the terminals 112 remain solid, and there is no melting or re-flowing of any solder.

The terminals 112 may be laid out in any suitable pattern on the surface of the DUT 110. In some cases, the terminals 112 may be in a generally square grid, which is the origin of an expression that describes the DUT 110, BGA, WL-CSP, QFN, DFN, TSOP, or DO for leaded parts. There may also be deviations away from a rectangular grid, including irregular spacing and geometries. It will be understood that the specific locations of the terminals may vary as needed, with corresponding locations of pads on the load board 170 and contacts on the socket 150 or housing being chosen to match those of the terminals 112. In general, the spacing between adjacent terminals 112 is in the range of 0.25 to 1.5 mm, with the spacing being commonly referred to as a “pitch”. When viewed from the side, as in FIG. 1C, the DUT 110 displays a line of terminals 112, which may optionally include gaps and irregular spacing. These terminals 112 are made to be generally planar, or as planar as possible with typical manufacturing processes. In many cases, if there are chips or other elements on the DUT 110, the protrusion of the chips is usually less than the protrusion of the terminals 112 away from the DUT 110.

The test assembly 120 of FIG. 1C includes a load board 170 (the PCB board). The load board 170 includes a load board substrate 174 and circuitry that is used to test electrically the DUT 110. Such circuitry may include driving electronics that can produce one or more AC voltages having one or more particular frequencies, and detection electronics that can sense the response of the DUT 110 to such driving voltages. The sensing may include detection of a current and/or voltage at one or more frequencies. In general, it is highly desirable that the features on the load board 170, when mounted, are aligned with corresponding features on the DUT 110. Typically, both the DUT 110 and the load board 170 are mechanically aligned to one or more locating features on the test assembly 120. The load board 170 may include one or more mechanical locating features, such as fiducials or precisely-located holes and/or edges, which ensure that the load board 170 may be precisely seated on the test assembly 120. These locating features typically ensure a lateral alignment (X, Y, see FIG. 1A) of the load board 170, and/or a longitudinal alignment (Z, see FIG. 1A) as well.

In general, the load board 170 may be a relatively complex and expensive component. The housing/test assembly 120 performs many functions including protecting the contact pads 172 of the load board 170 from wear and damage. Such an additional element may be an interposer socket 150. The socket 150 also mechanically aligns with the load board 170 with suitable locating features (not shown), and resides in the test assembly 120 above the load board 170, facing the DUT 110. The socket 150 includes a series of electrically conductive contacts 152, which extend longitudinally outward on either side of the socket 150. Each contact 152 may include a resilient element, such as a spring, an elastomer, or other suitable material, and is capable of conducting an electrical current to/from the load board 170 from/to the DUT 110 with sufficiently low resistance or impedance. Each contact 152 may be a single conductive unit, or may alternatively be formed as a combination of conductive elements. Each contact 152 connects one contact pad 172 on the load board 170 to one terminal 112 on the DUT 110, although there may be testing schemes in which one or multiple contact pads 172 connect to a single terminal 112, or multiple terminals 112 connect to a single contact pad 172. We assume in the text and drawings that a single contact 152 connects a single pad 172 to a single terminal 112, although it will be understood that any of the tester elements disclosed herein may be used to connect one or more contact pads 172 connect to a single terminal 112, or one or more terminals 112 to a single contact pad 172. Note that the contact forms the electrical connection 154 between the terminal 112 and the contact pad 172.

Typically, the socket 150 electrically connects the load board pads 172 and the bottom contact surface of the DUT 110. Although the socket 150 may be removed and replaced relatively easily, compared with removal and replacement of the load board 170, we consider the socket 150 to be part of the test assembly 120 for this document. During operation, the test assembly 120 includes the load board 170, the socket 150, and the mechanical construction that mounts them and holds them in place (not shown). Each DUT 110 is placed against the test assembly 120, is tested electrically, and is removed from the test assembly 120. A single socket 150 may test many DUTs 110 before it wears out, and may typically last for several thousand tests or more before requiring replacement. In general, it is desirable that replacement of the socket 150 be relatively fast and simple, so that the test assembly 120 experiences only a small amount of down time for socket replacement. In some cases, the speed of replacement for the socket 150 may even be more important than the actual cost of each socket 150, with an increase in tester up-time resulting in a suitable cost savings during operation.

FIG. 1C shows the relationship between the test assembly 120 and the DUTs 110. When each DUT 110 is tested, it is placed into a suitable robotic handler with sufficiently accurate placement characteristics, so that a particular terminal 112 on the DUT 110 may be accurately and reliably placed (in X, Y and Z, see FIG. 1A) with respect to corresponding contacts 152 on the socket 150 and corresponding contact pad 172 on the load board 170. The robotic handler (not shown) forces each DUT 110 into contact with the test assembly 120. The magnitude of the force depends on the exact configuration of the test, including the number of terminals 112 being tested, the force to be used for each terminal, typical manufacturing and alignment tolerances, and so forth. In general, the force is applied by the mechanical handler of the tester (not shown), acting on the DUT 110. In general, the force is generally longitudinal, and is generally normal of the load board 170.

FIG. 1D shows the test assembly 120 and DUT 110 in contact, with sufficient force being applied to the DUT 110 to engage the contacts 152 and form an electrical connection 154 between each terminal 112 and its corresponding contact pad 172 on the load board 170.

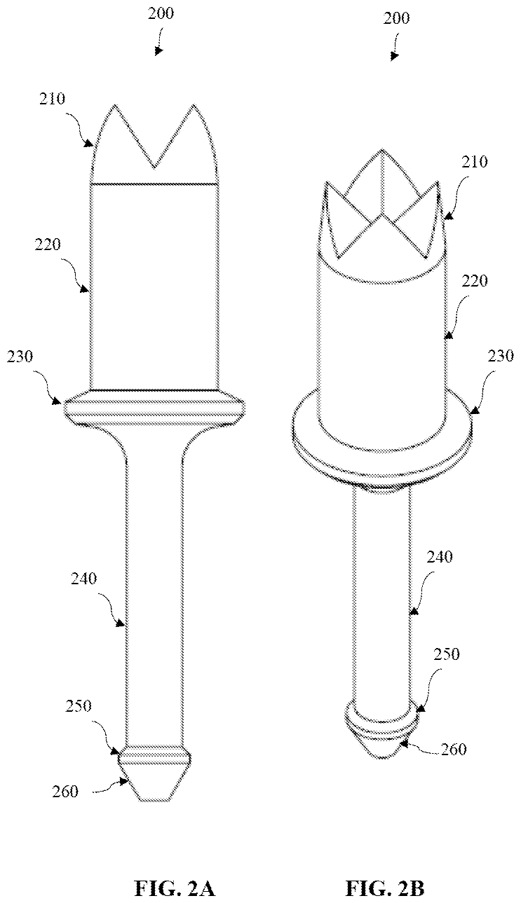

FIG. 2A is a side view of an upper plunger 200 of a probe contact assembly for a testing system, according to an embodiment. FIG. 2B is a perspective view of the upper plunger 200 of FIG. 2A, according to an embodiment. It is to be understood that the probe contact assembly (e.g., the contact 152 of FIGS. 1C and 1D) can be a complaint spring loaded probe contact assembly.

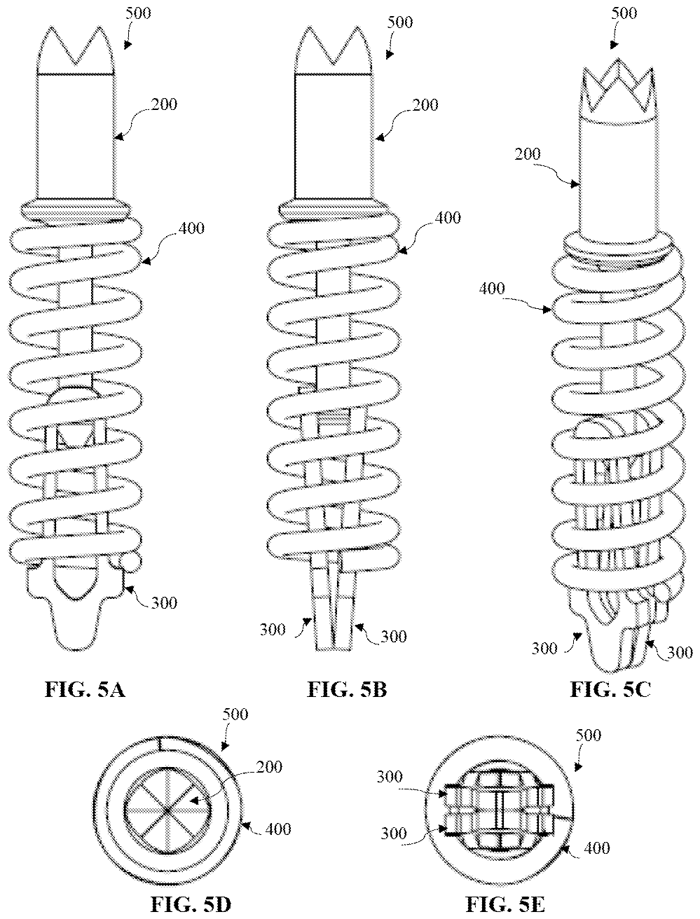

In an embodiment (see e.g., FIGS. 5A-5C), the probe contact assembly includes an upper plunger 200 (a DUT plunger), a biasing member 400 (shown is a compliant compression spring), and a pair of receivers 300 (aka, lower plungers, PCB plungers, or load board plungers). It is to be understood that the receivers can be a preferably identical or matched pair, but not necessarily so. It is also to be understood that in an embodiment, the biasing member 400 can be a spring or other object(s) other than a spring, which can provide a required resiliency. A top of the upper plunger 200 is configured to engage with the signal and power (S&P) terminals of the DUT. It is to be understood that the S&P terminals of the DUT can be pins, pads, leads, balls, lines, etc. In an embodiment, the top of the upper plunger 200 is configured to engage with a solder ball of a ball grid array (BGA) package. A bottom or bottoms of the receivers 300 is/are configured to engage with the signal and power (S&P) terminals of the PCB (i.e., the load board). It is to be understood that the S&P terminals of the PCB can be pins, pads, leads, lines, etc. In an embodiment, the bottom(s) of the receiver 300 is/are configured to engage with a pad on the PCB that makes electrical contact to a test apparatus. It is to be understood that the receivers 300 can be two separate identical components or a single piece integral component.

Back to FIGS. 2A and 2B, in an embodiment, the upper plunger 200 includes a DUT interface 210 (the top portion of the upper plunger 200), a DUT-side shaft 220, a shoulder 230, an internal shaft 240, and a retainer 250. In an embodiment, the retainer 250 includes an end 260.

In an embodiment, the DUT interface 210 can be a crown-shaped interface that is configured to engage with a BGA ball (an S&P terminal of the DUT). In other embodiments, the shape of the DUT interface 210 can be conical, spear, round, flat, or the like, depending on the interface type of the terminal of the DUT.

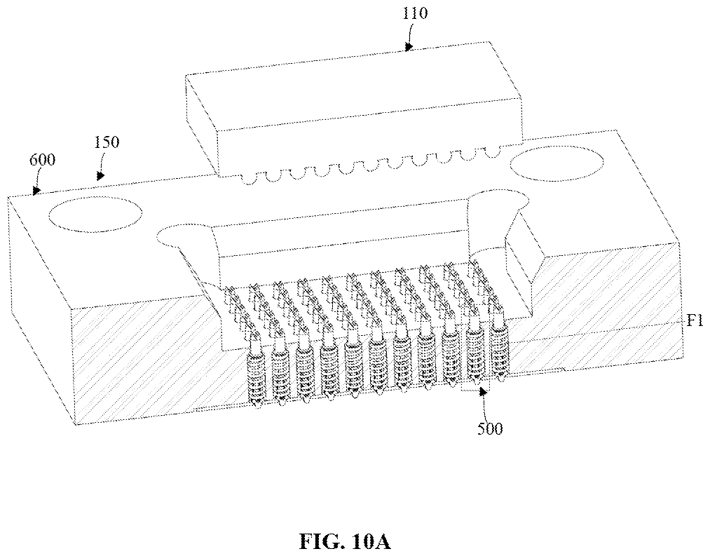

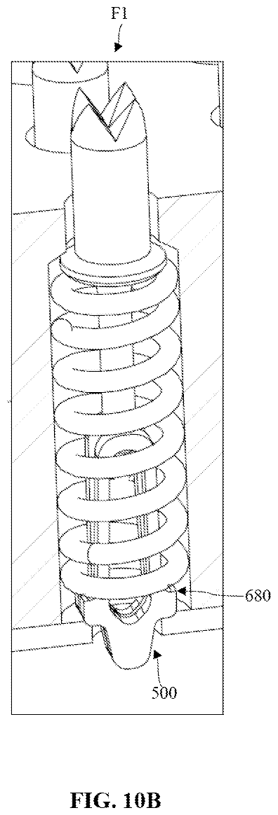

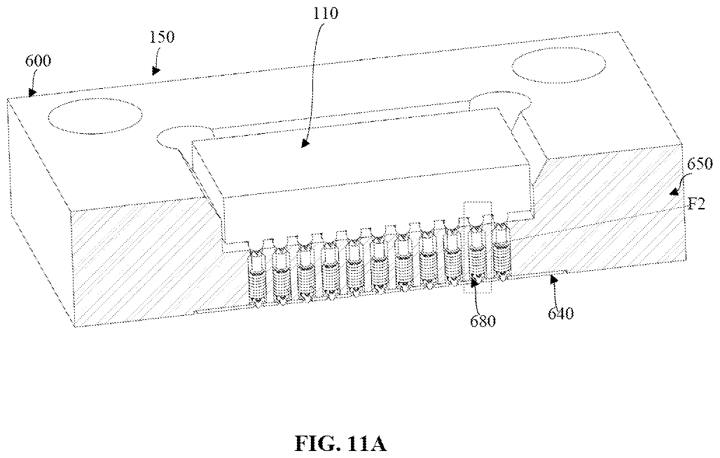

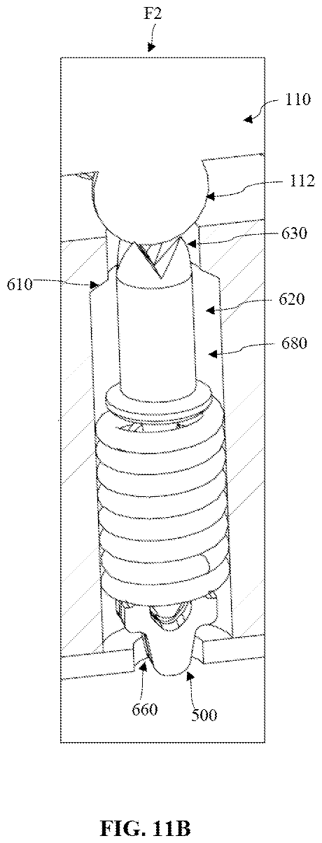

In an embodiment, the DUT-side shaft 220 can have a cylindrical shape or other suitable shape. A diameter of the shoulder 230 is greater than a diameter of the DUT-side shaft 220. The shoulder 230 can be configured to stop motion of the upper plunger 200 in a socket housing (see detailed descriptions in FIGS. 10A-11B) in a height direction (vertical direction or Z direction, see FIG. 1A) of the probe contact assembly, so that the probe contact assembly can be retained in the socket housing. In an embodiment, the shoulder 230 extends from the DUT-side shaft 220 with size/diameter of the shoulder 230 being gradually increased and then gradually decreased toward the internal shaft 240. In an embodiment, the largest width or diameter of the shoulder 230 can be the same as or close to an outer diameter of the spring 400, or between the outer diameter of the spring 400 and an inner diameter of the spring 400.

In an embodiment, the internal shaft 240 can be configured as a contact interface to the mating receivers (e.g., planar receivers) 300 that can slide along a length of the internal shaft 240 and make electrical contact. The diameter of the internal shaft 240 is smaller than the diameter of the shoulder 230 (and the diameter of the DUT-side shaft 220). In an embodiment, the internal shaft 240 can have a cylindrical shape or other suitable shape.

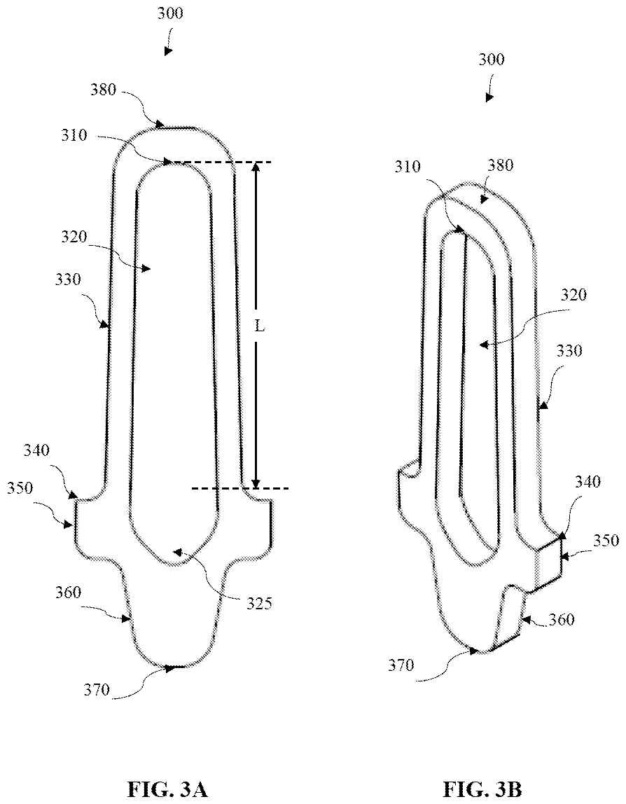

The retainer 250 is configured to retain the probe contact assembly together. In an embodiment, the retainer 250 can have a shape of a knob or other suitable shape, which can be partially received in the aperture 320 of the receiver(s) 300 (see FIGS. 3A and 3B). The end 260 of the retainer 250 can have a conical chamfered end that aids in the assembly of the probe contact assembly. In an embodiment, the retainer 250 extends from the internal shaft 240 with size/diameter of the retainer 250 being gradually increased and then gradually decreased toward the conical chamfered end 260. It is to be understood that a diameter of the retainer 250 can be greater than a width of aperture 300 to prevent the retainer 250 from passing through. A portion of the conical end 260 may be sized to be partly received within the aperture 320 so that the conical end 260 may slide along the aperture as the upper plunger is pushed (e.g., by the DUT). The sliding may preferably occur in the inner peripheral surface of the aperture 320. The end 260 need not be conical, but any shape which furthers a) partial passage through the aperture 320, and b) sliding along the inner surface with a minimum of friction but with fully electrical integrity and/or contact. The angle between the receiver 300 and the end 260 may further this objective.

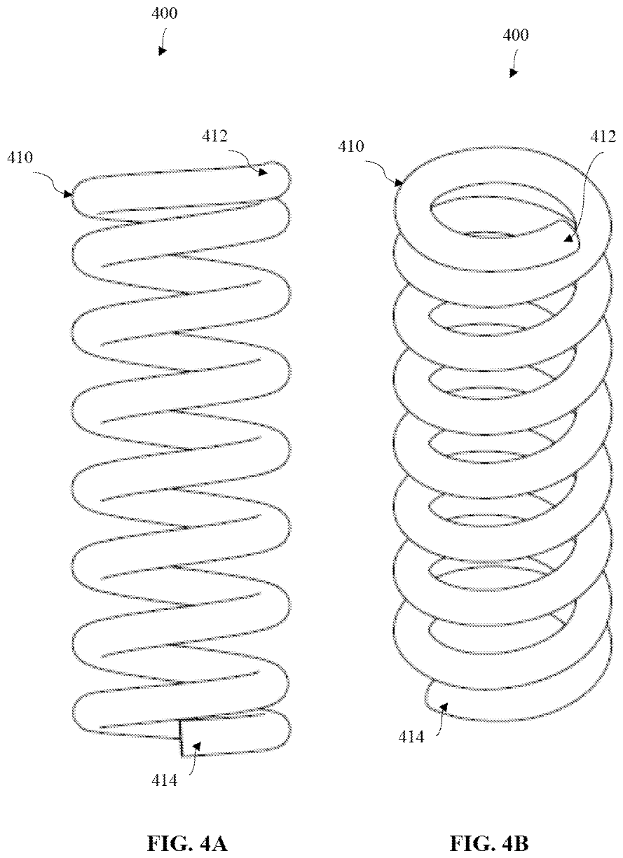

Back to FIGS. 2A and 2B, in an embodiment, a diameter of the shoulder 230 can be at or about 80% of the minimum DUT pitch. The minimum DUT pitch can refer to a spacing from center to center between the closest adjacent S&P terminals of the DUT. The minimum DUT pitch can be at or about 300 microns. A gap between the closest adjacent S&P terminals of the DUT can be at or about 30 microns. A diameter of the internal shaft 240 can be at or about 50% of a diameter of the shoulder 230. A diameter of the retainer can be at or about 20% larger than the diameter of the internal shaft 240. A length of the internal shaft 240 can be at or about 10% longer than a length of the spring 400 (see FIGS. 4A and 4B) when the spring 400 is fully compressed.

In an embodiment, the upper plunger 200 can be computer numeral control (CNC) turned on an automatic lathe machine. The upper plunger 200 can be plated or made from a solid metal or alloy material such as homogenous alloy including copper alloy, palladium alloy, etc. In an embodiment, the upper plunger 200 can be constructed from a flat metallic element. In an embodiment, the upper plunger 200 can be plated with gold or other conductive material. In an embodiment, a height of the upper plunger 200 can be at or about 500 microns to at or about 600 microns.

FIG. 3A is a front view of a receiver 300 of a probe contact assembly for a testing system, according to an embodiment. FIG. 3B is a perspective view of the receiver 300 of FIG. 3A, according to an embodiment.

It is to be understood that FIGS. 3A and 3B show one of a pair of the receivers 300. In an embodiment, two receivers 300 are used in a probe contact assembly. The receiver 300 can be manufactured as a flat component using etching, stamping, e-forming, water-jet cutting, or other suitable manufacturing processes. The material of the receiver 300 can be a copper alloy or other suitable metallic alloy. The receiver 300 can be gold-plated to enhance lubricity and electrical conductivity.

In an embodiment, the receiver 300 includes a top 380, an aperture 320 having an up-stop 310 and a clearance 325, a body 330, two shoulders 350 (in the width direction) each having a shoulder stop 340, a protrusion 360 having an end 370 (with decreased width in the Z direction). In an embodiment, the aperture 320 extends from the up-stop 310 to a position near a bottom of the shoulders 350 in a vertical direction (the height direction of the receiver 300). In the width direction (a direction from one shoulder 350 to another shoulder 350), a width of the bottom portion of the aperture 320 is gradually reduced. In an embodiment, the aperture 320 can be sized to receive a portion of the retainer 250, but narrow enough that the retainer 250 cannot pass therethrough. The aperture 320 may be of uniform width along its length or progressively wider toward the bottom, to assist in movement of the retainer 250, but still not wide enough for the retainer 250 to pass through.

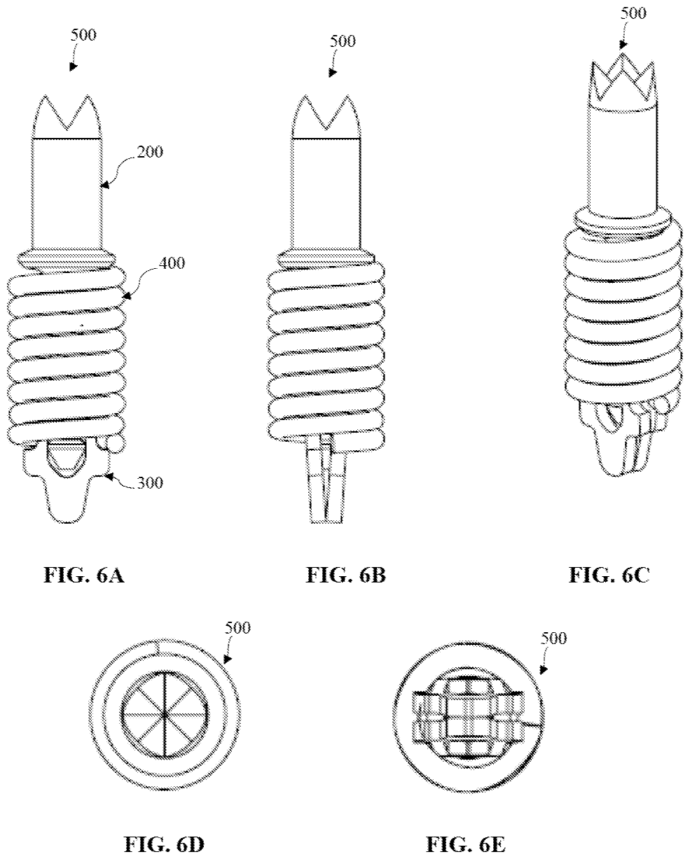

In an embodiment, the aperture 320 is where the retainer 250 of the upper plunger 300 slides vertically (e.g., from an uncompressed state of the probe contact assembly to a compressed state or vice versa). In the uncompressed state, the retainer 250 of the upper plunger 200 can stop on the up-stop 310 of the aperture 320. The body 330 preferably has a tapered outer surface, and the taper can be designed such that in an assembled state of the probe contact assembly, the taper can force the (sides of the) receiver pair 300 to come together to form a single contact point on the PCB in a progressively narrowing gap such as a “V” or substantially “V” shape (see e.g., FIGS. 5A-6C)., where the bottom ends of the receiver pair 300 are drawn close together and/or in complete abutment. The shoulder stop 340 can be configured to rest against an end coil of the spring 400. The shoulder (or flange) 350 can be a widest part of the receiver 300 and can be used to ensure that the probe contact assembly can be retained in a socket housing (see e.g., FIGS. 10A-11B). The end 370 of the protrusion 360 includes a contact surface to contact an S&P terminal of the PCB.

In an embodiment, a thickness (the direction into the paper in view of FIG. 3A) of the receiver 300 remains constant. A width or diameter (the largest width or diameter) of the shoulder 350 can be between an outer diameter of the spring 400 and an inner diameter of the spring 400. The extra clearance area 325 can be configured to allow for the retainer 250 to not bottom out on the receiver 300 (e.g., in the compressed state). The up-stop 310 is configured to be an up-stop of the retainer 250 when the probe contact assembly is in an uncompressed state. The body 330 can be tapered up to at or about 10% from the up-stop 310 to a lower portion of the body 330 (a length of the tapered portion is shown as “L” in a vertical direction). That is, along the “L” direction and within a length of the “L” portion, a width of the body 330 is gradually increased (tapered), and a width of the aperture 320 is also increased (tapered). For a lower portion of the aperture 320 (below the “L” portion), a width of the aperture 320 can be decreased (e.g., to prevent the retainer 250 from moving down toward the PCB). The rounded bottom surface of the end 370 can be configured to make a good contact with the pad of the PCB.

In an embodiment, the receiver 300 can be made of beryllium copper, copper alloy, nickel or nickel alloy, etc. The receiver 300 can be etched, made via metal additive manufacturing, through electroforming, etc. In an embodiment, the receiver 300 can be plated with gold or the like. In an embodiment, the receiver 300 can have a height of at or about 400 microns. It is to be understood that the bottom of the receiver 300 can be flat, round, etc. The receiver 300 can be manufactured with various methods (e.g., etched, electrical discharge machining, electroforming, stamping) at low cost.

It is also to be understood that there can be taper internal (e.g., in aperture 320) and external (on body 330) to the receiver 300 (a length of the tapered portion is shown as “L” in a vertical direction). The tapered portion can allow easy compression without jamming or binding, and can ensure that the receivers 300 are progressively narrowing, such that an e.g., V-shape or the like can be maintained (e.g., from an uncompressed state to a compressed state or vice versa). It is further to be understood that sides (in the thickness direction) of an upper portion (e.g., above or near the up-stop 310) of the receiver 300 can slide along and on the internal shaft 240 (e.g., from an uncompressed state to a compressed state or vice versa). Sides (in the thickness direction) of a lower portion (e.g., above or near or at the end 370) of the receiver 300 can contact with each other.

FIG. 4A is a side view of a spring 400 of a probe contact assembly for a testing system, according to an embodiment. FIG. 4B is a perspective view of the spring 400 of FIG. 4A, according to an embodiment. It is to be understood that the biasing member 400 (the resilient member such as a spring) can perform two functions: 1) it can provide compression or resilience between the upper plunger 200 and the receiver(s) 300 and, 2) it can bind the combination of the upper plunger 200 and the receiver(s) 300 together at all times during normal operation so that they not only do not fall part, but also insure electrical contact between the upper plunger 200 and the receiver(s) 300 thereby providing an electrical path between the DUT and load board.

In an embodiment, the spring 400 (having a body 410 and two ends (412, 414)) is a compression spring wound from a resilient metallic wire on a precision winding machine. The spring end coils (412, 414) can be “closed” such that there can be little to no gap on the end coils (412, 414) to e.g., aid in assembly. It is to be understood that there is a gap between the spring coils of the body 410. The wire material of the spring 400 has a constant wire diameter. The outer diameter of the spring 400 remains constant throughout the length of the spring 400. The number of coil turns of the spring 400 can vary depending on the electrical and mechanical requirements. The spring 400 can be made of metal such as stainless steel alloy, etc. The spring 400 can be gold-plated to enhance the electrical performance of the probe contact assembly and to provide lubricity when the probe contact assembly is compressed.

It is to be understood that when compressed, the resilient spring 400 can create or cause a z-axis (in the height direction) compliance in the socket. The inner diameter, the outer diameter, and the diameter of the wire of the spring 400 are constant, respectively. The spacing between the coils of the spring 400 can allow compression, and when the probe contact assembly 500 is in a compressed state, the coils of the spring 400 can still have spacing (that is, the spring 400 may not deform and can last longer) except that there can be little to no gap on the end coils (412, 414).

FIG. 5A is a front view of a probe contact assembly 500 for a testing system, according to an embodiment. FIG. 5B is a side view of the probe contact assembly 500 of FIG. 5A, according to an embodiment. FIG. 5C is a perspective view of the probe contact assembly 500 of FIG. 5A, according to an embodiment. FIG. 5D is a top view of the probe contact assembly 500 of FIG. 5A, according to an embodiment. FIG. 5E is a bottom view of the probe contact assembly 500 of FIG. 5A, according to an embodiment.

FIGS. 5A-5E illustrate the probe contact assembly 500 in an uncompressed state. It is to be understood that the uncompressed state may refer to a state in which the probe contact assembly 500 is assembled and the spring 400 is in a free or uncompressed condition. As shown in FIG. 5B, the two receivers 300 are assembled from a bottom of the probe contact assembly 500 and sides of lower portions of the receivers 300 contact with each other in a “V” or substantially “V” shape. The spring 400 is captured between the shoulder 230 of the upper plunger 200 and the shoulder stops 340 of the shoulders 350 of the receivers 300. The retainer 250 of the upper plunger 200 is resting against the up-stops 310 of the apertures 320 of the receivers 300. Since the body 330 (extending from one shoulder stop 340 to the top 380 and then to another shoulder stop 340 in the width direction) of the receivers 300 are constrained to the inner diameter of the spring 400, the probe contact assembly 500 can be self-contained and cannot fall apart.

It is to be understood that the above retention system (i.e., the retainer 250 with the spring 400 retaining the components of the probe contact assembly 500 together) can be more robust as compared to existing technologies that rely on latches. In contrast, latch geometries have to be precisely manufactured in order to properly work, and latches on components often wear away during the use of the probe or probe assembly, thus losing the holding power. The retention system disclosed herein does not have the limitation of latches and the receivers 300 can hold over the retainer 250 over a wide manufacturing tolerance, thus reducing cost and complexity.

FIG. 6A is a front view of a probe contact assembly 500 (in a compressed state) for a testing system, according to another embodiment. FIG. 6B is a side view of the probe contact assembly 500 of FIG. 6A, according to another embodiment. FIG. 6C is a perspective view of the probe contact assembly 500 of FIG. 6A, according to another embodiment. FIG. 6D is a top view of the probe contact assembly 500 of FIG. 6A, according to another embodiment. FIG. 6E is a bottom view of the probe contact assembly 500 of FIG. 6A, according to another embodiment.

FIGS. 6A-6E illustrate the probe contact assembly 500 in a compressed state. It is to be understood that the compressed state may refer to a state in which the probe contact assembly 500 is assembled and the spring 400 is in a fully compressed condition. The probe contact assembly 500 can be compressed when the DUT (e.g., a semiconductor device) is pushed down onto the tip (e.g., the crown-shaped interface, etc.) of the probe contact assembly 500. The resultant spring force can insure a good electrical contact interface to the DUT. As shown in FIG. 6B, in the compressed state, the retainer 250 of the upper plunger 200 is moved to a bottom of the aperture 320 of the receiver(s) 300, and the “V” shaped configuration of the receivers 300 remains in place. The “V” shaped configuration can provide a good sliding contact between (the internal shaft of) the upper plunger and (sides of the upper portions of) the receivers 300. It is to be understood that in the compressed state, due to the shape of the aperture 320 and the retainer 250, there is a clearance area 325 between the retainer 250 and the bottom of the aperture 320.

It is to be understood that during testing, most electrical current and resistance may be from the upper and receivers (which form a primary path of the electrical current) for better RF performance. It is also to be understood that there could be some or minimum electrical current passing through the spring.

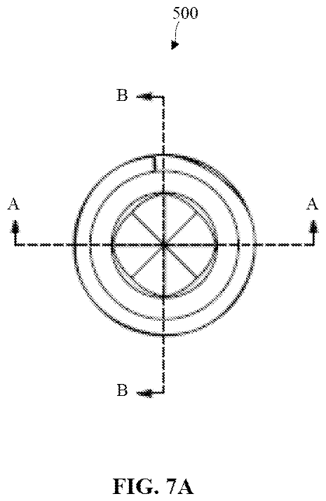

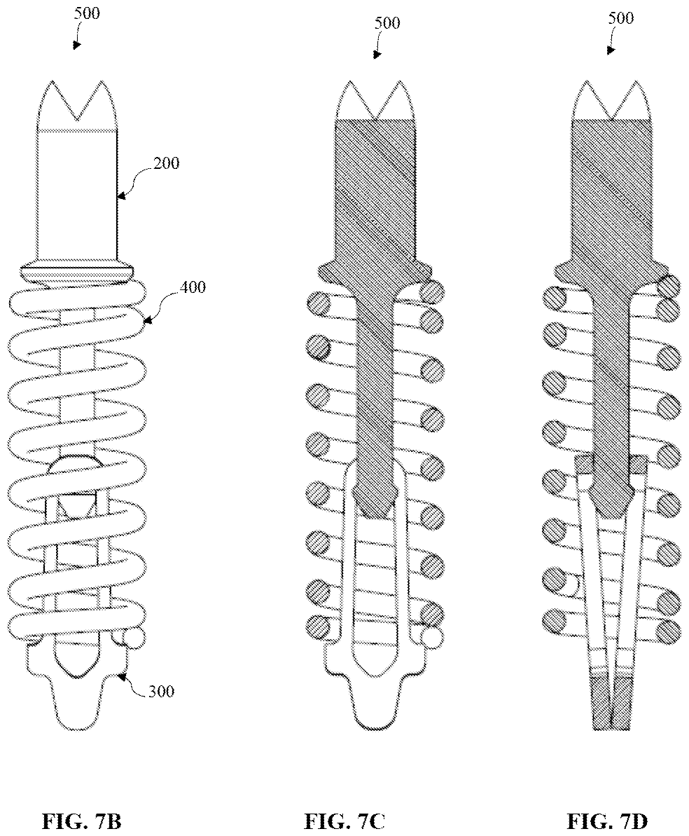

FIG. 7A is a top view of a probe contact assembly 500 for a testing system, according to an embodiment. FIG. 7B is a front view of the probe contact assembly 500 of FIG. 7A, according to an embodiment. FIG. 7C is a cross-sectional view of the probe contact assembly 500 of FIG. 7A along the line A-A, according to an embodiment. FIG. 7D is a cross-sectional view of the probe contact assembly 500 of FIG. 7A along the line B-B, according to an embodiment. FIGS. 7A-7D illustrate the probe contact assembly 500 in an uncompressed state.

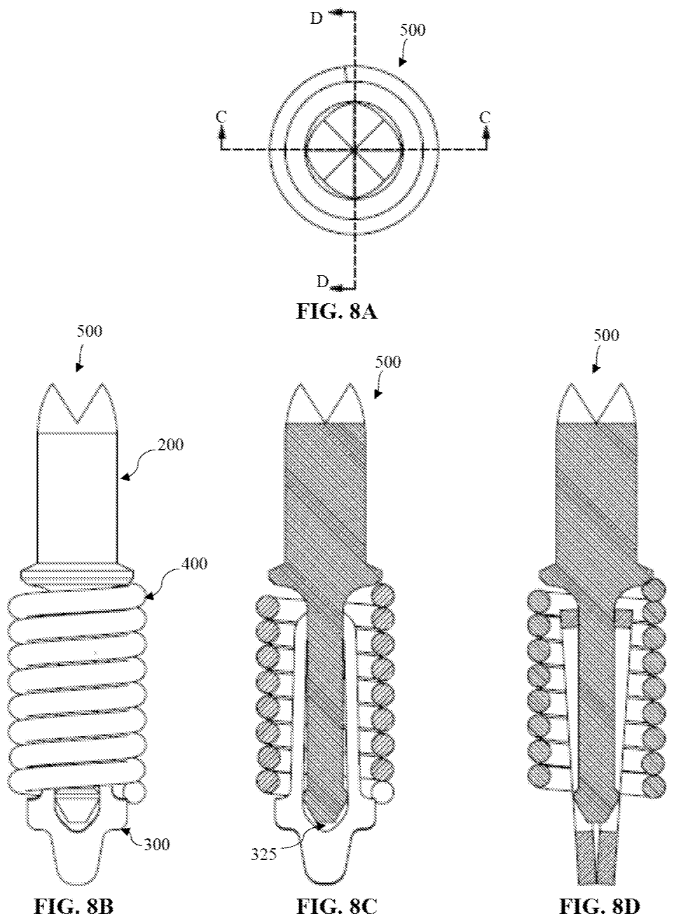

FIG. 8A is a top view of a probe contact assembly 500 (in a compressed state) for a testing system, according to another embodiment. FIG. 8B is a front view of the probe contact assembly 500 of FIG. 8A, according to another embodiment. FIG. 8C is a cross-sectional view of the probe contact assembly 500 of FIG. 8A along the line C-C, according to another embodiment. FIG. 8D is a cross-sectional view of the probe contact assembly 500 of FIG. 8A along the line D-D, according to another embodiment. FIGS. 8A-8D illustrate the probe contact assembly 500 in a compressed state. In the compressed state, the whole retainer 250 or a part of the retainer 250 extends outside of the spring 400. A top of the retainer 250 is at or near the shoulder stop 340.

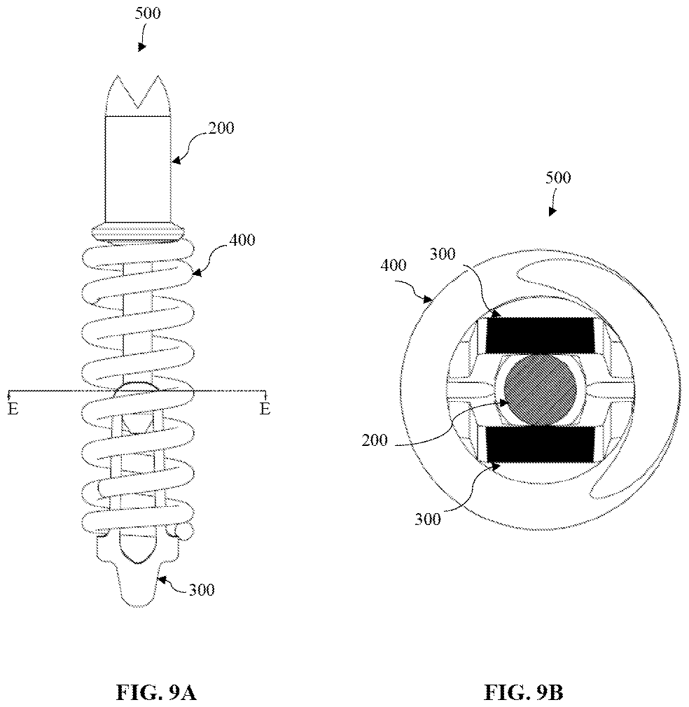

FIG. 9A is a front view of a probe contact assembly 500 for a testing system, according to an embodiment. FIG. 9B is a cross-sectional view of the probe contact assembly 500 of FIG. 9A along the line E-E, according to an embodiment. FIGS. 9A-9B illustrate the probe contact assembly 500 in an uncompressed state.

As shown in FIG. 9B, the internal shaft 240 of the upper plunger 200 separates the receivers 300 from each other at an upper portion of the receivers 300. Four corners of the receivers 300 (two outer corner for each receiver 300) contact the inner surface of the spring 400. The geometries of the retainer 250 and the receivers 300 and the inner diameter of the spring 400 are configured such that if there is any biasing force outward (in a direction towards outside of the spring 400) that is trying to disassemble the probe contact assembly 500, the receivers 300 may run into the spring 400 and get restricted. It is to be understood that there is no press fit between the receivers 300 and the spring 400 so that the receivers 300 can slide along the length of the internal shaft 240.

FIG. 10A is a cross sectional perspective view of a plurality of probe contact assemblies 500 housed in a socket housing 600, according to an embodiment. FIG. 10B is an enlarged view of a portion F1 of FIG. 10A, illustrating a probe contact assembly 500 housed in a contact cavity (e.g., a counter-drilled hole, a counterbore, a counterbored hole, etc.) of a socket housing 600, according to an embodiment. FIGS. 10A-10B illustrate the probe contact assembly 500 in an uncompressed state.

FIG. 11A is a cross sectional perspective view of a plurality of probe contact assemblies 500 (in a compressed state) housed in a socket housing 600, according to an embodiment. FIG. 11B is an enlarged view of a portion F2 of FIG. 11A, illustrating a probe contact assembly 500 housed in a contact cavity (e.g., a counter-drilled hole, a counterbore, a counterbored hole, etc.) of a socket housing 600, according to an embodiment. FIGS. 11A-11B illustrate the probe contact assembly 500 in a compressed state.

As shown in FIGS. 10A-11B, the socket 150 (see FIGS. 1A-1D) includes a housing 600. The housing 600 includes a housing body 650 having a plurality of cavities or holes (e.g., counter-drilled holes, counterbores, counterbored holes, etc.) 680, each cavity being configured to house a probe contact assembly 500. In an embodiment, the housing 600 can be made of a non-conductive material such as plastic, ceramic, etc. A thin retainer plate 640 can hold the probe contact assemblies 500 in place on the bottom of the probe contact assemblies 500. The retainer plate 640 can be a flat plate with simple through-holes 660 to reduce the overall complexity of the socket 150 (including the housing 600 and the probe contact assemblies 500), or a counterbored plate. In an embodiment, a thickness of the retainer plate 640 can be at or about 0.05 mm. The retainer plate 640 can be screwed, taped, or otherwise mounted or fixed on the housing body 650. The cavity or hole 680 includes a first cavity (e.g., a counterbore or the like) 630, an up-stop 610, and a second cavity 620.

As shown in FIGS. 10A-10B, each of the probe contact assemblies 500 can be situated in a housing cavity (the cavity 680) in an uncompressed or a free state. The shoulder 230 is resting against the up-stop 610. The up-stop 610 is configured to prevent or stop the shoulder 230 from moving up towards the DUT 110. A bottom of the shoulders 350 of the receivers 300 is resting against the retainer plate 640. The retainer plate 640 is configured to prevent or stop the shoulders 350 from moving down towards the PCB (the load board). The DUT interface 210 and an upper portion of the DUT-side shaft 220 are positioned outside of or above the cavity 630. A lower portion of the DUT-side shaft 220 is housed inside of the cavity 630. The shoulder 230 and the spring 400 are housed inside the cavity 620. The protrusion 360 and its end 370 pass through the through-hole 660 of the retainer plate 640, and a portion of the protrusion 360 and/or its end 370 is positioned outside of or below the through-hole 660. In an embodiment, a diameter of the cavity 630 is less than a diameter of the cavity 620 and is less than a diameter of the shoulder 230. A diameter of the through-hole 660 is less than a diameter of the cavity 620 and is less than a width of the shoulder 350 but greater than a width of the protrusion 360 and its end 370.

When the probe contact assembly 500 is in a compressed state, the socket 150 is mounted to the PCB (not shown) and the DUT 110 (e.g., the terminal(s) 112 of the DUT 110) is compressing the probe contact assembly 500. As shown in FIGS. 11A-11B, the contact assembly 500 is fully compressed by the DUT 110. The DUT interface 210 is pushed down to at or near a top surface of the housing 600. The shoulder 230 is pushed away from the up-stop 610 down into the cavity 620. The spring 400 is compressed. The end 370 of the protrusion 360 is at or near a bottom surface of the retainer plate 640. The shoulder 350 is pushed away from the retainer plate 640 up into the cavity 620. In an embodiment, the compressed length of the probe contact assembly is at or about 1 millimeter.

It is to be understood that the shape (e.g., a round shape, etc.) or diameter of the contact assembly 500 can match the shape (e.g., a round shape, etc.) or diameter of the cavity of the housing 600.

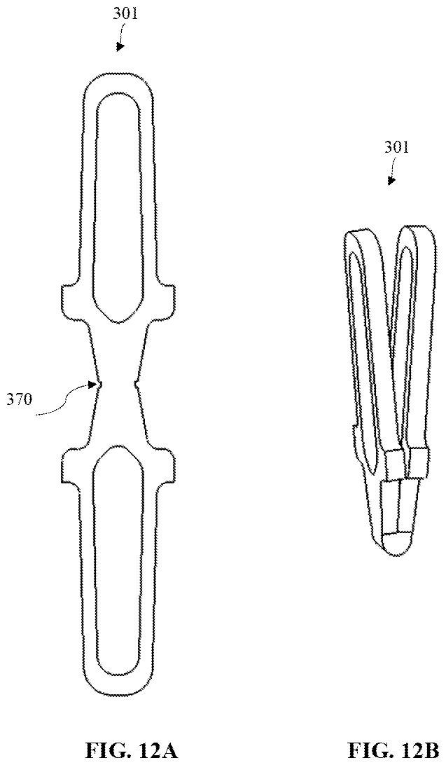

FIG. 12A is a front view of a receiver 301 (in a flat state as manufactured) of a probe contact assembly for a testing system, according to another embodiment. FIG. 12B is a perspective view of the receiver 301 (in a folded state) of FIG. 12A, according to another embodiment.

It is to be understood that the receiver 301 can be a single integral piece. That is, the receiver 301 can replace the two separate receivers 300 with a single part that is made as a joined piece (e.g., joined at or near the location of the ends 370 of the protrusions 360), then folded up to make the “V” shaped assembly (see FIG. 12B). The folded receiver 301 can then snap over the upper plunger 200. It is also to be understood that the probe contact assembly with a single integral receiver 301 may function identically to the embodiment with two separate receivers 300.

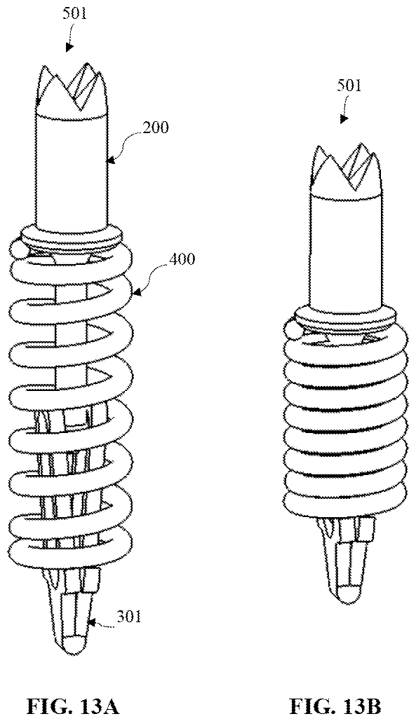

FIG. 13A is a perspective view of a probe contact assembly 501, according to an embodiment. FIG. 13B is a perspective view of a probe contact assembly 501 in a compressed state, according to another embodiment. The probe contact assembly 501 includes an upper plunger 200, a spring 400, and a receiver 301. FIG. 13A illustrates a probe contact assembly 501 in an uncompressed state. FIG. 13B illustrates the probe contact assembly 501 in a compressed state.

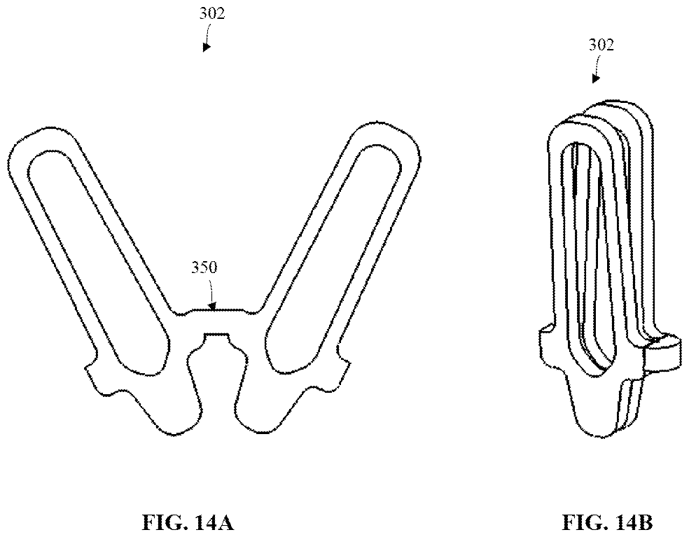

FIG. 14A is a front view of a receiver 302 (in a flat state as manufactured) of a probe contact assembly for a testing system, according to yet another embodiment. FIG. 14B is a perspective view of the receiver 302 (in a folded state) of FIG. 14A, according to yet another embodiment.

It is to be understood that the receiver 302 can be a single integral piece. That is, the receiver 302 can replace the two separate receivers 300 with a single part that is made as a joined piece (e.g., joined at or near the location of the sides of the shoulders 350), then folded sideway to make the “V” shaped assembly. The folded receiver 302 can then snap over the upper plunger 200. It is also to be understood that the probe contact assembly with a single integral receiver 302 may function identically to the embodiment with two separate receivers 300.

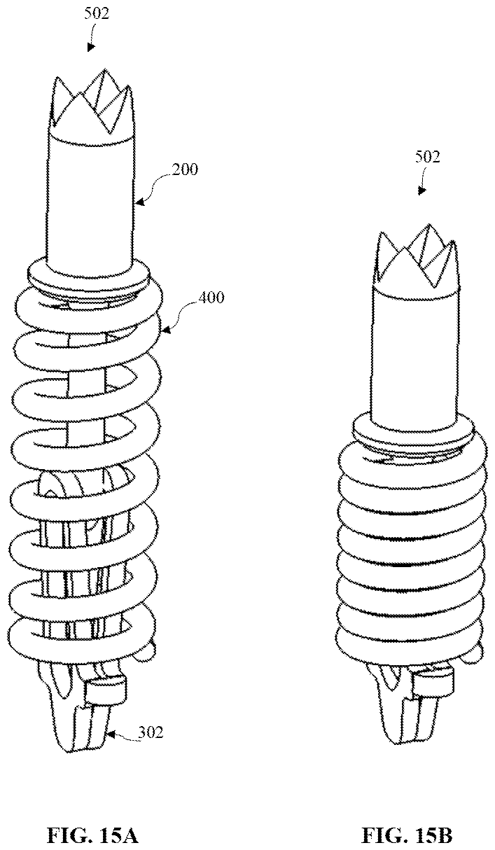

FIG. 15A is a perspective view of a probe contact assembly 502, according to an embodiment. FIG. 15B is a perspective view of a probe contact assembly 502 in a compressed state, according to another embodiment. The probe contact assembly 502 includes an upper plunger 200, a spring 400, and a receiver 302. FIG. 15A illustrates a probe contact assembly 502 in an uncompressed state. FIG. 15B illustrates the probe contact assembly 502 in a compressed state.

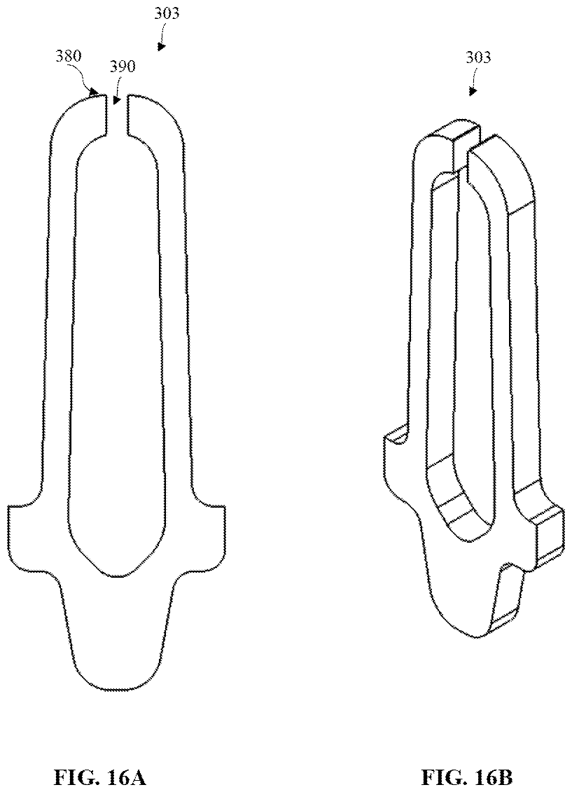

FIG. 16A is a front view of a receiver 303 of a probe contact assembly for a testing system, according to yet another embodiment. FIG. 16B is a perspective view of the receiver 303 of FIG. 16A, according to yet another embodiment. The receiver 303 is the same as the receiver 300, except that the receiver 303 includes a gap 390 at the top 380 for allowing a manufacturing process. The gap 390 extends from the aperture 320 to an outer top surface of the plunger 303.

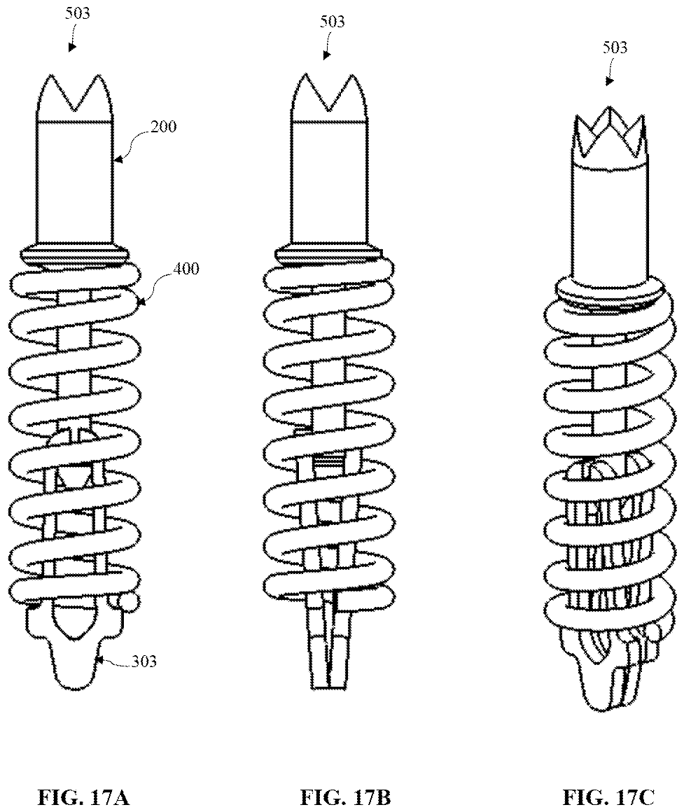

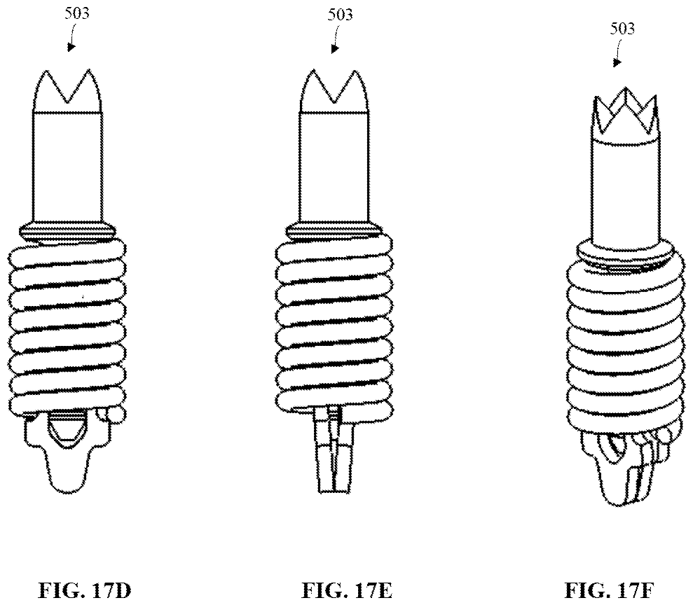

FIG. 17A is a front view of a probe contact assembly 503, according to an embodiment. FIG. 17B is a side view of the probe contact assembly 503 of FIG. 17A, according to an embodiment. FIG. 17C is a perspective view of the probe contact assembly 503 of FIG. 17A, according to an embodiment. FIG. 17D is a front view of a probe contact assembly 503 in a compressed state, according to another embodiment. FIG. 17E is a side view of the probe contact assembly 503 of FIG. 17D, according to another embodiment. FIG. 17F is a perspective view of the probe contact assembly 503 of FIG. 17D, according to another embodiment. The probe contact assembly 503 includes an upper plunger 200, a spring 400, and a pair of receivers 303.

The description of the invention and its applications as set forth herein is illustrative and is not intended to limit the scope of the invention. Variations and modifications of the embodiments disclosed herein are possible and practical alternatives to and equivalents of the various elements of the embodiments would be understood to those of ordinary skill in the art upon study of this patent document. These and other variations and modifications of the embodiments disclosed herein may be made without departing from the scope and spirit of the invention.

Aspects

It is noted that any one of aspects below can be combined with each other.

Aspect 1. A compliant probe contact assembly for a testing system for testing integrated circuit devices, the contact assembly comprising: an upper plunger including a first shoulder separating an upper shaft from a lower shaft, and a retainer proximate an end of the lower shaft; a first receiver and a second receiver configured to engage with the upper plunger, each of the first and second receivers including a second shoulder having a shoulder stop; and a biasing member, wherein when the contact assembly is assembled, the biasing member is captured between a bottom of the first shoulder and the shoulder stops of the first and second receivers, the upper plunger separates sides of upper portions of the first and second receivers, and sides of lower portions of the first and second receivers contact with each other.

Aspect 2. The contact assembly according to aspect 1, wherein the retainer, the lower shaft, and the upper portions of the first and second receivers are constrained to an inner space of the biasing member.

Aspect 3. The contact assembly according to aspect 1 or aspect 2, wherein when the contact assembly is assembled, the first and second receivers form a substantially V-shape.

Aspect 4. The contact assembly according to any one of aspects 1-3, wherein when the contact assembly is assembled, the contact assembly has an uncompressed state and a compressed state, when the contact assembly is in the uncompressed state, the retainer is resting against up-stops of apertures of the first and second receivers.

Aspect 5. The contact assembly according to aspect 4, wherein when the contact assembly is in the compressed state, the retainer is near a bottom of the apertures of the first and second receivers, and a clearance area is formed between the retainer and the bottom of the apertures.

Aspect 6. The contact assembly according to any one of aspects 1-5, wherein the first receiver and the second receiver are separate components.

Aspect 7. The contact assembly according to any one of aspect 1-6, wherein the first receiver and the second receiver join together and form a single integral component.

Aspect 8. The contact assembly according to aspect 7, wherein the first and second receivers join at a bottom end of the first and second receivers.

Aspect 9. The contact assembly according to aspect 7, wherein the first and second receivers join at the second shoulders of the first and second receivers.

Aspect 10. The contact assembly according to any one of aspects 1-9, wherein each of the first and second receivers includes a gap at a top of the first and second receivers.

Aspect 11. A testing system for testing integrated circuit devices, comprising: a device under test (DUT); a load board; and a compliant probe contact assembly including: an upper plunger including a first shoulder separating an upper shaft from a lower shaft, and a retainer proximate an end of the lower shaft; a first receiver and a second receiver configured to engage with the upper plunger, each of the first and second receivers including a second shoulder having a shoulder stop; and a biasing member, wherein when the contact assembly is assembled, the biasing member is captured between a bottom of the first shoulder and the shoulder stops of the first and second receivers, the upper plunger separates sides of upper portions of the first and second receivers, and sides of lower portions of the first and second receivers contact with each other, wherein the upper plunger includes a DUT interface configured to engage with the DUT, an end of the first and second receivers is configured to engage with the load board.

Aspect 12. The testing system according to aspect 11, wherein the DUT is a device having a ball grid array package.

Aspect 13. The testing system according to aspect 11 or aspect 12, further comprising: a housing configured to house the contact assembly.

Aspect 14. The testing system according to aspect 13, further comprising: a socket, the socket including the housing and the contact assembly, wherein the socket is configured to provide a pathway from inputs and outputs of the DUT to inputs and outputs of the load board, respectively.

Aspect 15. The testing system according to aspect 13, wherein the housing includes a hole configured to house the contact assembly, the hole includes an up-stop between a first cavity and a second cavity, the second cavity has a diameter greater than a diameter of the first cavity.

Aspect 16. The testing system according to aspect 15, wherein the up-stop of the hole is configured to prevent the first shoulder from moving up towards the DUT.

Aspect 17. The testing system according to aspect 15, further comprising: a retainer plate disposed at a bottom of the housing.

Aspect 18. The testing system according to aspect 17, wherein the retainer plate includes a through-hole configured to allow a bottom end of the first and second receivers to pass through.

Aspect 19. The testing system according to aspect 18, wherein a diameter of the through-hole is smaller than the diameter of the second cavity of the housing.

Aspect 20. A compliant probe contact assembly for a testing system for testing integrated circuit devices, the contact assembly comprising: a plunger including a retainer proximate an end of a lower shaft; first and second receiver plates having a top and a bottom, each receiver plate having a longitudinal aperture sized to receive only a portion of the retainer, the aperture being not wide enough to allow the retainer to pass therethrough; and a biasing member, wherein the first and second receiver plates are aligned relative to each other so that the first and second receiver plates are progressively closer to each other at the bottom relative to the top; wherein when the contact assembly is assembled, the biasing member surrounds at least a portion of the plunger and receives the first and second receiver plates thereby holding the first and second receiver plates and the retainer in physical and electrical contact as the plunger moves long the aperture of the first and second receiver plates.

The terminology used in this specification is intended to describe particular embodiments and is not intended to be limiting. The terms “a,” “an,” and “the” include the plural forms as well, unless clearly indicated otherwise. The terms “comprises” and/or “comprising,” when used in this specification, specify the presence of the stated features, integers, steps, operations, elements, and/or components, but do not preclude the presence or addition of one or more other features, integers, steps, operations, elements, and/or components.

With regard to the preceding description, it is to be understood that changes may be made in detail, especially in matters of the construction materials employed and the shape, size, and arrangement of parts without departing from the scope of the present disclosure. This specification and the embodiments described are exemplary only, with the true scope and spirit of the disclosure being indicated by the claims that follow.

What is claimed is:

1. A compliant probe contact assembly for a testing system for testing integrated circuit devices, the contact assembly comprising:
an upper plunger including a first shoulder separating an upper shaft from a lower shaft, and a retainer proximate an end of the lower shaft;
a first receiver and a second receiver configured to engage with the upper plunger, each of the first and second receivers including a second shoulder having a shoulder stop; and
a biasing member,
wherein when the contact assembly is assembled, the biasing member is captured between a bottom of the first shoulder and the shoulder stops of the first and second receivers, the upper plunger separates sides of upper portions of the first and second receivers, and sides of lower portions of the first and second receivers contact with each other.

2. The contact assembly according to claim 1, wherein the retainer, the lower shaft, and the upper portions of the first and second receivers are constrained to an inner space of the biasing member.

3. The contact assembly according to claim 1, wherein when the contact assembly is assembled, the first and second receivers form a progressively narrowing gap.

4. The contact assembly according to claim 1, wherein when the contact assembly is assembled, the contact assembly has an uncompressed state and a compressed state,
when the contact assembly is in the uncompressed state, the retainer is resting against up-stops of apertures of the first and second receivers.

5. The contact assembly according to claim 4, wherein when the contact assembly is in the compressed state, the retainer is near a bottom of the apertures of the first and second receivers, and a clearance area is formed between the retainer and the bottom of the apertures.

6. The contact assembly according to claim 1, wherein the first receiver and the second receiver are separate components.

7. The contact assembly according to claim 1, wherein the first receiver and the second receiver join together and form a single integral component.

8. The contact assembly according to claim 7, wherein the first and second receivers join at a bottom end of the first and second receivers.

9. The contact assembly according to claim 7, wherein the first and second receivers join at the second shoulders of the first and second receivers.

10. The contact assembly according to claim 1, wherein each of the first and second receivers includes a gap at a top of the first and second receivers.

11. A testing system for testing integrated circuit devices, comprising:
a device under test (DUT);
a load board; and
a compliant probe contact assembly including:
an upper plunger including a first shoulder separating an upper shaft from a lower shaft, and a retainer proximate an end of the lower shaft;
a first receiver and a second receiver configured to engage with the upper plunger, each of the first and second receivers including a second shoulder having a shoulder stop; and
a biasing member,
wherein when the contact assembly is assembled, the biasing member is captured between a bottom of the first shoulder and the shoulder stops of the first and second receivers, the upper plunger separates sides of upper portions of the first and second receivers, and sides of lower portions of the first and second receivers contact with each other,
wherein the upper plunger includes a DUT interface configured to engage with the DUT, an end of the first and second receivers is configured to engage with the load board.

12. The testing system according to claim 11, wherein the DUT is a device having a ball grid array package.

13. The testing system according to claim 11, further comprising:
a housing configured to house the contact assembly.

14. The testing system according to claim 13, further comprising:
a socket, the socket including the housing and the contact assembly,
wherein the socket is configured to provide a pathway from inputs and outputs of the DUT to inputs and outputs of the load board, respectively.

15. The testing system according to claim 13, wherein the housing includes a hole configured to house the contact assembly, the hole includes an up-stop between a first cavity and a second cavity, the second cavity has a diameter greater than a diameter of the first cavity.

16. The testing system according to claim 15, wherein the up-stop of the hole is configured to prevent the first shoulder from moving up towards the DUT.

17. The testing system according to claim 15, further comprising:
a retainer plate disposed at a bottom of the housing.

18. The testing system according to claim 17, wherein the retainer plate includes a through-hole configured to allow a bottom end of the first and second receivers to pass through.

19. The testing system according to claim 18, wherein a diameter of the through-hole is smaller than the diameter of the second cavity of the housing.

20. A compliant probe contact assembly for a testing system for testing integrated circuit devices, the contact assembly comprising:
a plunger including a retainer proximate an end of a lower shaft;
first and second receiver plates having a top and a bottom, each receiver plate having a longitudinal aperture sized to receive only a portion of the retainer, the aperture being not wide enough to allow the retainer to pass therethrough; and
a biasing member,
wherein the first and second receiver plates are aligned relative to each other so that the first and second receiver plates are progressively closer to each other at the bottom relative to the top;
wherein when the contact assembly is assembled, the biasing member surrounds at least a portion of the plunger and receives the first and second receiver plates thereby holding the first and second receiver plates and the retainer in physical and electrical contact as the plunger moves long the aperture of the first and second receiver plates.
